(19) United States
(12) Patent Application Publication
(10) Pub. No.: US 2025/0259831 A1
(43) Pub. Date: Aug. 14, 2025

(54) WIRELESS MEASUREMENT CHARACTERIZATION

(71) Applicant: Applied Materials, Inc., Santa Clara, CA (US)

(72) Inventors: ANKE HELLMICH, Kahl (DE); AMIR BAYATI, San Jose, CA (US); CHRISTOPHER MALMS, Hanau Hessen (DE); LINDSAY HARDISON, Santa Clara, CA (US)

(21) Appl. No.: 18/436,423

(22) Filed: Feb. 8, 2024

(51) Int. Cl. H01J 37/32; H01L 21/683

(52) U.S. Cl. CPC H01J 37/32935; H01J 37/32724; H01L 21/6833; H01J 2237/24585

(57) ABSTRACT

Embodiments disclosed herein comprise an apparatus for sensing plasma conditions in a chamber. In an embodiment, the apparatus comprises a housing with a plasma sensor on a surface of the housing. In an embodiment, the apparatus further comprises a computing system within the housing and electrically coupled to the plasma sensor. In an embodiment, the computing system comprises a battery, a board, a processing unit on the board, and a memory coupled to the processing unit. In an embodiment, a wireless communication module may be coupled to the processing unit.

### BACKGROUND

### 1) Field

Embodiments relate to the field of semiconductor manufacturing and, in particular, wireless measurement device characterization of chamber environments.

### 2) Description of Related Art

Plasma processing operations are used throughout the manufacture of semiconductor devices. However, monitoring the properties of the plasma is difficult. For example, properties, such as electron density, ion flux, and/or ion energy distribution are useful for determining the performance of a given processing operation. When plasma properties are well known for a given process, optimization of the process is made more achievable.

Currently, plasma properties are determined through the use of devices such as a retarding field energy analyzer (RFEA). An RFEA includes a series of conductive screens that are applied in a stack. The screens are each held at different voltages in order to allow for ions with a specific energy to reach a collector plate. The current generated in the collector plate can be used to determine one or more of the plasma properties under investigation. However, RFEA solutions have significant limitations. One limitation is that the RFEA is placed into a plasma chamber manually.

### SUMMARY

Embodiments disclosed herein include an apparatus for sensing plasma conditions in a chamber. In an embodiment, the apparatus includes a housing with a plasma sensor on a surface of the housing. In an embodiment, the apparatus further comprises a computing system within the housing and electrically coupled to the plasma sensor. In an embodiment, the computing system comprises a battery, a board, a processing unit on the board, and a memory coupled to the processing unit. In an embodiment, a wireless communication module may be coupled to the processing unit.

Embodiments may further include a method of characterizing a plasma in a chamber. In an embodiment, the method comprises delivering a sensor device to the chamber without the chamber being vented. In an embodiment, the sensor device comprises a housing and a plasma sensor on the housing. The sensor device may also comprise a computing system within the housing that comprises a battery, a processor, and a wireless communications system. In an embodiment, the method may further comprise measuring a plasma property within the chamber with the sensor device, and removing the sensor device from the chamber without the chamber being vented.

Embodiments disclosed herein may further include a semiconductor processing tool. In an embodiment, the semiconductor processing tool may comprise a factory interface, a transfer chamber, a load lock coupled between the factory interface and the transfer chamber, and a processing chamber coupled to the transfer chamber. In an embodiment, the processing chamber comprises a pedestal for supporting a substrate, an exhaust line for removing gasses from the processing chamber, a plasma source opposite from the pedestal, and an antenna within the processing chamber, wherein the antenna has a wired connection to outside of the processing chamber.

### BRIEF DESCRIPTION OF THE DRAWINGS

FIG. 1 is a plan view illustration of a semiconductor processing tool that is compatible with a sensor device that can be passed throughout the processing tool with wafer handling robots, in accordance with an embodiment.

FIG. 2A is a perspective view illustration of a sensor device with a housing with a top surface that comprises a plurality of plasma sensors, in accordance with an embodiment.

FIG. 2B is a perspective view illustration of a sensor device with a lid removed to show internal components of the sensor device, in accordance with an embodiment.

FIG. 2C is a plan view illustration of a board within the sensor device that schematically illustrates electrical components for operating the sensor device, in accordance with an embodiment.

FIG. 3 is a cross-sectional illustration of a plasma sensor, in accordance with an embodiment.

FIG. 4A is a plan view illustration of a plasma sensor with a group of holes through the housing that is centered on a top surface of the plasma sensor, in accordance with an embodiment.

FIG. 4B is a plan view illustration of a plasma sensor with a group of holes through the housing that is offset from a center of a top surface of the plasma sensor, in accordance with an embodiment.

FIG. 4C is a plan view illustration of sensor device with an array of plasma sensors distributed across a top surface of the sensor device, in accordance with an embodiment.

FIGS. 5A-5C are plan view illustrations of a sensor device that is rotated about several positions in order to read plasma properties across an entire surface of a substrate, in accordance with an embodiment.

FIG. 5D is a plan view illustration of a sensor device with an alternative sensor layout pattern, in accordance with an embodiment.

FIG. 6 is a cross-sectional illustration of a plasma chamber with integrated antennas for accommodating a sensor device with wireless communication functionality, in accordance with an embodiment.

FIG. 7 is a process flow diagram of a process for measuring a plasma property in a chamber without venting the chamber, in accordance with an embodiment.

FIG. 8, is a process flow diagram of a process for wirelessly waking up a sensor device and taking plasma property measurements within a chamber, in accordance with an embodiment.

FIG. 9 is a process flow diagram of a process for taking plasma property measurements within a chamber and stopping the plasma process when a temperature of the sensor device gets too high, in accordance with an embodiment.

FIG. 10 illustrates a block diagram of an exemplary computer system that may be used in conjunction with a processing tool, in accordance with an embodiment.

### DETAILED DESCRIPTION

Embodiments described herein include wireless measurement device characterization of chamber environments. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, plasma property information is used in order to develop processes, tune processes, and/or implement chamber matching between two or more processes. Existing processes for determining plasma properties include the use of a retarding field energy analyzer (RFEA). The RFEA measures a current of a collector plate, where the current is the result of impacts from ions of the plasma.

The RFEA is placed into the plasma chamber manually. This typically requires the chamber to be vented. That is, the vacuum of the chamber is released in order to open the chamber and insert the RFEA. Venting a chamber is a costly process. The venting takes the chamber off-line for a long duration. For example, venting and re-seasoning the chamber after the measurement process may take up to a day or longer. Further, the venting process disturbs the operating conditions of the chamber. As such, the measured values may not truly replicate the fully seasoned conditions used during operation of the chamber.

Further, existing RFEA devices include a wired communication system. This requires the wire to be routed through a vacuum port in the chamber in order to communicate with an outside device. Wired solutions are currently favored because the plasma chamber is essentially a Faraday cage, and it is difficult to send wireless electromagnetic communications outside of the plasma chamber.

As such, embodiments disclosed herein can address several limitations in RFEA solutions, such as: 1) the requirement of placing a measurement devices into a process chamber manually; and 2) the need for the RFEA cable to pass through a port in the process chamber in order to transmit data to an external device. Avoiding a manual insert of the RFEA into the chamber eliminates the need for venting the process chamber. A wireless protocol in combination with a receiving antenna configuration within the process chamber allows for wireless communication with a device that is external to the process chamber.

Accordingly, embodiments disclosed herein include sensor devices that are able to be inserted into a plasma chamber through existing wafer transfer operations. That is, the sensor device may have a form factor and weight that is comparable to that of a semiconductor wafer (e.g., a silicon wafer). For example, the sensor device may have a diameter of a standard wafer size (e.g., 200 mm, 300 mm, 450 mm, etc.), with a thickness that is less than approximately 10 mm, or approximately 6 mm or less. A mass of the sensor device may be approximately 1,000 grams or less, or approximately 500 grams or less. Accordingly, the sensor device can be manipulated by transfer robots within a semiconductor processing tool, and the sensor device can fit through ports, doors, load locks, and/or the like within the semiconductor processing tool.

The ability to transfer in a sensor device without venting has significant benefits. For example, the down time of the chamber is significantly reduced. Without venting, measurements can be made by the sensor device in less than an hour, less than half an hour, or less than fifteen minutes in some embodiments. Additionally, there is no need to re-season or change any other parameters of the process. This makes the measured process much more similar (if not exactly the same) as the current on-line performance of the chamber. The combination of reduced time for measurement and improved similarity with on-line performance renders the information from the sensor device more useful for process development, process control, chamber matching, and/or the like.

Sensor devices described herein may also comprise wireless communication functionality. In one embodiment, the sensor device comprises RF antennas that allow for frequency modulation in order to send data into and out of the chamber. Other embodiments may include an integrated antenna and communication protocol, such as Bluetooth. However, instead of sending the signal from the sensor device directly outside the chamber, embodiments may include an intermediate antenna that is integrated into the chamber (e.g., in an exhaust line, on the pedestal, etc.). The intermediate antenna may include a wired connection to a device external to the chamber.

Embodiments disclosed herein include architectures and systems that allow for integration of multiple components into the small form factor necessary for such a portable device sensor. For example architecture and design improvements for battery solutions, electrical circuitry/components, and/or the like may be used in order meet the form factor demands of such a portable device sensor.

Embodiments disclosed herein also include system protection and/or battery life improvement features. Since the sensor device will be exposed to a plasma environment, temperature control of the system is beneficial to prevent the sensor device from overheating. For example, when a temperature sensor within the sensor device indicates a maximum temperature has been reached, the sensor device may send an alert signal to the controller of the plasma chamber in order to stop the plasma process. Such an interlock feature may prevent damage to components, such as the battery, of the sensor device.

With respect to battery life improvement, the sensor device may be transported while in a sleep state. Once within the chamber, a wake-up signal can be delivered to the sensor device. Upon receiving the wake-up signal, the sensor device can begin taking plasma measurements. A sleep signal can be transmitted to the sensor device after the plasma process in order to return the sensor device back to a sleep state.

Embodiments disclosed herein include sensor devices that comprise RFEA sensors. These sensors (sometimes referred to as “buttons”) may include a stack of electrically conductive screens that are held at different voltages. The screens and their applied voltages allow for certain ions to pass to a collector plate. Current within the collector plate can be correlated to different plasma properties. While RFEA sensors are described in greater detail herein, it is to be appreciated that many different sensor types may be compatible with embodiments disclosed herein. For example, the sensors may comprise one or more of an RFEA, a Faraday cup, an ion angle measurement sensor, or a radical sensor. Embodiments may also comprise sensor devices with sensors for detecting conditions or properties within a chamber other than plasma properties. For example, temperatures, pressures, electromagnetic radiation intensities and/or frequencies, and/or the like may also be measured with sensor devices in accordance with embodiments disclosed herein.

In an embodiment, the sensors may have holes through the housing that are centered with a top surface of the sensor housing. In other embodiments, the sensors may include holes that are offset from a center of the housing. For example, the group of holes may be provided towards an edge of the top surface of the sensor housing. This may be beneficial when the sensor is provided near an edge of the sensor device in order to measure plasma properties all of the way to an edge of a substrate.

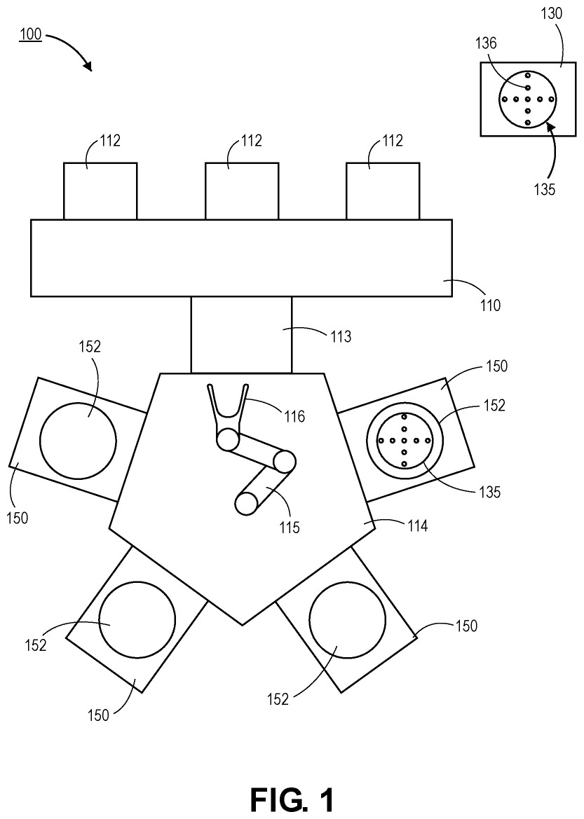

Referring now to FIG. 1, a plan view illustration of a semiconductor processing tool 100 is shown, in accordance with an embodiment. In an embodiment, the semiconductor processing tool 100 may sometimes be referred to as a cluster tool, an inline tool, or the like since there are a plurality of chambers 150 coupled within a single system. The plurality of chambers 150 may all include the same type of chamber, or the plurality of chambers 150 may include two or more different types of chambers. While four chambers 150 are shown, it is to be appreciated that embodiments disclosed herein may be compatible with semiconductor processing tools 100 that comprise one or more chambers 150. In an embodiment, the chambers 150 may include one or more of, a deposition chamber, an etch chamber, a resist deposition (e.g., spin-coating) chamber, an annealing chamber, an exposure chamber (e.g., an ultraviolet exposure tool, such as a deep ultraviolet (DUV) exposure tool, an extreme ultraviolet (EUV) exposure tool, etc.), a resist develop chamber, or the like.

In an embodiment, two or more of the chambers 150 may be coupled to a transfer chamber 114. The transfer chamber 114 may comprise a wafer handling robot 115. The wafer handling robot 115 may be a multi-axis robot device. The wafer handling robot 115 may comprise an end effector 116 or the like to secure and transport wafers or sensor devices 135 between chambers 150. In an embodiment, the transfer chamber 114 may be maintained at a sub-atmospheric pressure, such as a vacuum pressure.

In an embodiment, a load lock 113 may couple the transfer chamber 114 to a factory interface (FI) 110. The FI 110 may couple with one or more front opening unified pods (FOUPS) 112. A robot (not shown) within the FI 110 may transfer wafers (or sensor devices 135) between the FOUPs 112 and the load lock 113. The load lock 113 may be a transition between an atmospheric pressure (e.g., in the FI 110) and a vacuum pressure (e.g., in the transfer chamber 114).

In an embodiment, one or more sensor devices 135 may be transported within the semiconductor processing tool 100 and the rest of the fab with robotic systems. For example, a sensor device 135 is shown as being supported on a pedestal 152 (e.g., an electrostatic chuck (ESC)) within the first chamber 150 from the load lock 113 (in a clockwise direction). This sensor device 135 may have initially been delivered to the semiconductor processing tool 100 in FOUP 112. The FOUP 112 may have been unloaded by a robot in the FI 110, passed through the load lock 113, and moved from the load lock 113 to the chamber 150 by the wafer handling robot 115.

In an embodiment, the sensor device 135 may have a form factor and mass that are similar to a typical wafer handled by the semiconductor processing tool 100 (e.g., a 200 mm wafer, a 300 mm wafer, a 450 mm wafer, etc.). A more detailed description of the components of the sensor device 135 and how the sensor device 135 is packaged into such a form factor is described in greater detail below. Generally, the sensor device 135 may comprise one or more sensors 136. The sensors 136 may include plasma sensors. In a particular embodiment, the plasma sensors are RFEA sensors, similar to those described in greater detail herein. Though, it is to be appreciated that other types of sensors (including sensors for detecting non-plasma related properties) may be included on the sensor device 135.

In an embodiment, the sensor device 135 may be a battery operated device. Accordingly, the sensor device 135 may be charged after use or after any suitable duration of use. In some embodiments, the charging of the sensor device 135 may be implemented at a docking station 130. The docking station 130 may include structures for coupling to a battery in the sensor device 135 in order to charge the battery. The structures may include a plug, or wireless power delivery solutions (e.g., inductive coils, etc.). The docking station 130 may also include data connection capabilities (e.g., wireless or wired) in order to transfer data to and/or from the sensor device 135. In an embodiment, the docking station 130 may be a stationary device that does not move. In other embodiments, the docking station 130 may be part of a FOUP 112 or other transport device.

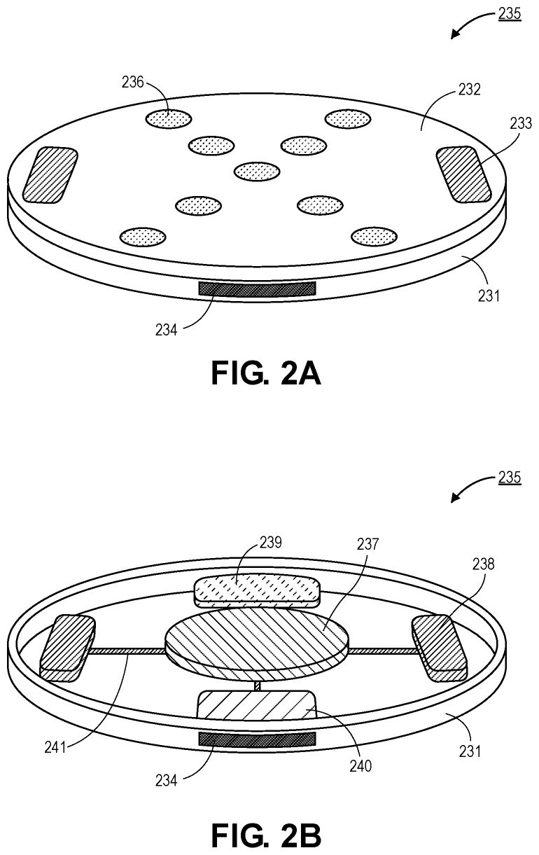

Referring now to FIGS. 2A-2C, a series of illustrations that depict a structure of a sensor device 235 is shown, in accordance with an embodiment. FIG. 2A is a perspective view of the entire housing of the sensor device 235. FIG. 2B is a perspective view of the sensor device 235 with the lid removed to illustrate internal components. FIG. 2C is a plan view schematic illustration of a board within the sensor device that houses electrical components, processors, circuitry, and/or the like.

Referring now to FIG. 2A, a perspective view illustration of the sensor device 235 is shown, in accordance with an embodiment. In an embodiment, the sensor device 235 may comprise an outer housing. In the illustrated embodiment, the outer housing comprises a lower housing 231 and a lid 232. The lower housing 231 and the lid 232 may be coupled together with any suitable fastener or fasteners (e.g., a clamp, a screws, a magnet, etc.). In an embodiment, the seal between the lower housing 231 and the lid 232 may be a hermetic seal. Though, more permeable seals may also be used in some embodiments. An O-ring, gasket, or the like (not visible in FIG. 2A) may be provided between the lower housing 231 and the lid 232 in some embodiments. While a particular housing configuration is shown in FIG. 2A, it is to be appreciated that the housing may include any structure that provides the necessary robustness to be transported within a semiconductor fabrication (or fab) environment.

In an embodiment, the lower housing 231 and/or the lid 232 may comprise any suitable materials. For example, aluminum, aluminum nitride, a sintered aluminum nitride powder, a ceramic, a light metal alloy, a machinable glass, or the like may be used for the lower housing 231 and/or the lid 232. The lower housing 231 and/or the lid 232 may be anodized or sputter coated in some embodiments. Anodizing or sputter coating the lower housing 231 and/or the lid 232 may be beneficial for arc protection. Embodiments may include the use of a material with a high thermal conductivity in order to improve temperature control.

In an embodiment, the lower housing 231 may comprise one or more ports 234. The port 234 may provide access to components (not shown) within the housing. For example, the port 234 may allow for a power cable or the like to be coupled to a battery within the housing. The port 234 may be a complete opening through the lower housing 231. In other embodiments, the port 234 may be a plug interface that still maintains a seal between an interior and an exterior of the sensor device 235. The port 234 may also be a window for wireless communication, such as Bluetooth.

In an embodiment, one or more sensors 236 may be distributed across a top surface of the lid 232. In the illustrated embodiment, nine sensors 236 are provided in a cross-configuration as one example. The sensors 236 may include any suitable sensor device. In some embodiments, the sensors 236 are used for plasma monitoring. For example, the sensors 236 may comprise RFEA devices. The sensors 236 may be set into recesses in the lid 232 so that a top surface of the sensor 236 is substantially coplanar with a top surface of the lid 232. In an embodiment, the sensors 236 may be retained in the recesses with any coupling device such as, a screw, a magnet, an adhesive, a retaining arm or component, or the like. Electrical contact to a bottom of the sensors 236 may be provided with a spring-loaded contact solution in some embodiments.

In an embodiment, one or more windows 233 may also be provided over a surface of the lid 232. The windows 233 may be dielectric material that allows for electromagnetic radiation to be transmitted out of the housing. For example, an antenna (not visible) may be provided below each of the windows 233. The dielectric material may comprise a ceramic material or the like.

In an embodiment, the sensor device 235 may comprise a form factor that is similar to form factors of standard wafers (e.g., silicon wafers). For example, the sensor device 235 may have a diameter that is approximately 200 mm, approximately 300 mm, approximately 450 mm, or the like. Additionally, a thickness of the sensor device 235 may be approximately 10 mm or less, or approximately 6 mm or less. In order to accommodate transport with wafer handling robots, the sensor device 235 may have a weight that is approximately 1,000 grams or less, or approximately 500 grams or less. As used herein, “approximately” may refer to a range of values that is within ten percent of the stated value. For example, approximately 10 mm may refer to a range of values from 9 mm to 11 mm.

Referring now to FIG. 2B, a perspective view illustration of the sensor device 235 with the lid 232 removed is shown, in accordance with an embodiment. Removal of the lid 232 exposes internal components that may be present within the sensor device 235. In an embodiment, the sensor device 235 may comprise a board 237. The board 237 may be a printed circuit board (PCB) or the like. Electrical components, routing, and/or the like may be provided on the board 237, as will be described in greater detail with respect to FIG. 2B.

In an embodiment, multiple additional components may be electrically coupled to the board 237 by cables 241, wires, and/or other electrical interconnect solutions. In one embodiment, one or more antennas 238 may be coupled to the board 237. The antennas 238 may be RF antennas that emit (and/or receive) electromagnetic radiation in order to implement wireless communications to/from the sensor device 235. The antennas 238 used in some sensor devices 235 may be suitable for frequency modulation and/or amplitude modulation. Such modulation processes may allow for enhanced abilities to send and receive information across the walls of a plasma chamber.

In an embodiment, one or more of the additional components may include a battery 240. The battery 240 may be a rechargeable battery, such as a solid state battery. Suitable solid state batteries may include any solid state electrolyte. For example, solid state electrolytes such as a ceramic or a glass may be used in some embodiments. In an embodiment, the battery 240 is compatible with vacuum environments and temperatures typical of a plasma processing environment. For example, the battery 240 may withstand temperatures up to approximately 80° C., up to approximately 120° C., up to approximately 150° C., or up to approximately 200° C. The battery 240 may also have an energy density that is capable of providing up to approximately 1 hour of scanning operation, or up to approximately 30 minutes of scanning operation (with scans being implemented at intervals of once per second, once per ten seconds, once per thirty second, or once per minute). Though other scanning frequencies may also be used in some embodiments.

The battery 240 may be charged by connecting a cable to the battery 240 through a port 234. The battery 240 may incorporate inductive coils and/or the like in order to enable wireless charging of the battery 240. In other embodiments, the battery 240 may be replaced periodically. An associated charging circuitry (not shown) may be included within the sensor device 235 around (e.g., on the board 237) and/or on the battery 240.

In an embodiment, an expansion slot 239 may also be provided within the sensor device 235. The expansion slot 239 may be useful for including an extra battery 240, antenna 238, and/or the like. This may allow for enhanced scanning time, improved wireless performance, redundancy, or other benefits to the sensor device 235.

Referring now to FIG. 2C, a plan view illustration of a schematic view of the board 237 within the sensor device 235 is shown, in accordance with an embodiment. In an embodiment, the board 237 may comprise a processor 243. In an embodiment, the processor 243 may include a central processing unit (CPU), an application specific integrated circuit (ASIC), or the like. The processor 243 may implement software instructions for initiating, controlling, and/or stopping the scanning of the sensors 236. The processor 243 may also control data collection, data processing, and/or the like. The processor 243 may control data transmission, battery control, and/or the like. In an embodiment, the processor 243 may implement any of the processes or methods (or portions of the processes or methods) described in greater detail herein. A memory 245 may be coupled to the processor 243. The memory 245 may be any suitable non-transitory computer readable medium. The memory 245 may be configured to store instructions for operating the processor 243. The memory 245 may also be configured to store data obtained from the sensors 236.

In an embodiment, the board 237 may include any number of components for processing or otherwise handling data received from the sensors 236. For example an analog to digital converter (ADC) 242 may convert an analog signal from the sensors 236 to a digital signal that can be handled by the processor 243.

In an embodiment, the board 237 may also comprise a pressure sensor 247. The pressure sensor 247 may be useful to determine when the sensor device 235 is within a vacuum environment. This may be useful since RFEA sensors 236 may be susceptible to arcing and/or other damage if operated at atmospheric conditions.

In an embodiment, the board 237 may also comprise a temperature sensor 246. The temperature sensor 246 may be used in order to protect the sensor device 235 from excessive temperatures. For example, if the temperature sensor 246 reads a temperature over a maximum threshold, the processor 243 may be configured to send out an alert to an external device that controls the plasma chamber. The alert may result in the plasma process being stopped. When at an elevated temperature, as detected by the temperature sensor 246, the sensor device 235 may also be delivered to a cooling chamber of the semiconductor processing tool in order bring down a temperature of the sensor device 235.

In an embodiment, the board 237 may also comprise a wireless communications module 244. The wireless communications module 244 may include one or more antennas and/or transceiver lines and circuitry for propagating and receiving wireless signals. In an embodiment, the wireless communications module 244 may operate at approximately 2.4 GHz. For example, wireless communications module 244 may operate in accordance with suitable communications protocols, such as Bluetooth and/or the like. The use of such wireless protocols may allow for increased data transmission speed compared to frequency modulation techniques. For example, such wireless protocols may have transmission speeds that are one or more orders of magnitude faster than the use of frequency modulation. As will be described in greater detail herein, such embodiments allow for transmission out of plasma chambers through the use of an intermediate antenna that is integrated into an interior of the plasma chamber. In an embodiment, electrical features of the wireless communications module 244 may be chosen for one or more of high breakdown voltage, high switching frequency, or high current capabilities. Transistor technologies that may satisfy one or more of such design parameters may include those formed with gallium-arsenide (GaAs) material systems. Monolithic microwave integrated circuit (MMIC) systems may also be used in some embodiments. In an embodiment, one or more of the components on the board 237 (or any electrical component within the sensor device 235 may comprises a coating to prevent outgassing (e.g., Paralyne).

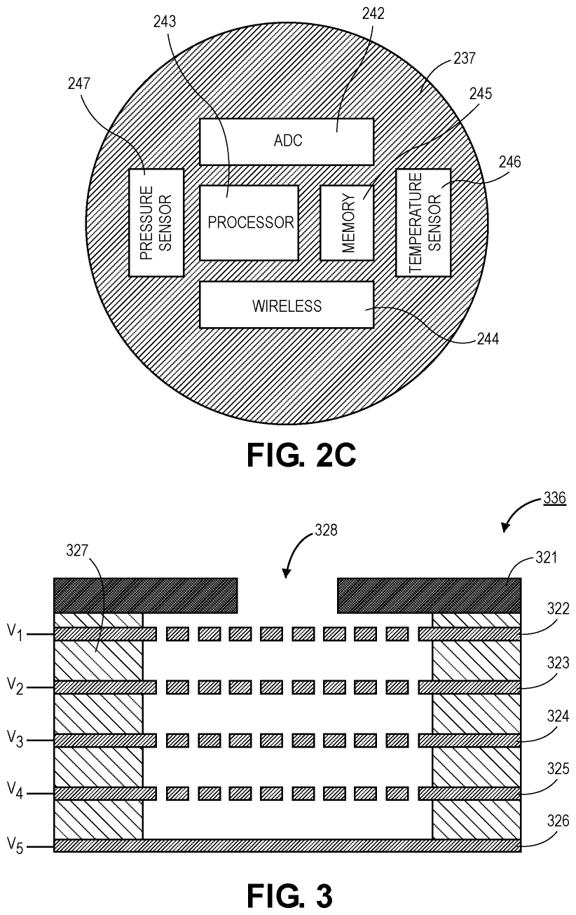

Referring now to FIG. 3, a cross-sectional illustration of a sensor 336 is shown, in accordance with an embodiment. In an embodiment, the sensor 336 may be an RFEA sensor 336. The RFEA sensor 336 may comprise a housing 321 with one or more holes 328. The holes 328 may allow species from the plasma (not shown) to pass into an interior of the sensor 336. In an embodiment, the interior of the RFEA sensor 336 may comprise a plurality of electrically conductive screens 322, 323, 324, 324, and 325 that are arranged in a stack. The screens may each be held at different voltages V1-V4. A collector plate 326 may be provided at a bottom of the screen stack, and the collector plate 326 may be held at a voltage V5. The screens 322-325 and the collector plate 326 may be separated from each other by electrically insulating layers 327.

In an embodiment, the top screen 322 may be used to prevent plasma formation within the RFEA sensor 336. The next screen 323 may be an electron repulsion screen. The screen 323 repels electrons by having a voltage V2 that is negative. The next screen 324 may be a discriminator screen that controls the flow of electrons to the collector plate 326. In some embodiments, the third voltage V3 may be scanned between a range in order to control the flow of ions through the RFEA sensor 336. The bottom screen 325 may be a secondary electron suppression screen. The voltage V4 may be negatively biased with respect to the voltage V5 of the collector plate 326 to create a retarding potential for repelling secondary electrons that are generated from the impact of ions with the collector plate 326.

In the embodiment shown in FIG. 3, the holes through the screens 322-325 are substantially vertical. This is useful for measuring ions that enter the hole 328 in a vertical path. However, not all ions will have a vertical path, and there may be some percentage of off-angle ions. In some embodiments, one or more screens may be added to the RFEA sensor 336 with holes that have different angles in order to measure ion angle distributions as well.

In FIG. 3, an RFEA sensor 336 is described in detail as being one type of sensor that can be integrated into sensor devices described herein. However, it is to be appreciated that other types of sensors, such as a Faraday cup, an ion angle measurement sensor, or a radical sensor may be used in the sensor device. Embodiments may also comprise sensor devices with sensors for detecting conditions or properties within a chamber other than plasma properties. For example, temperatures, pressures, electromagnetic radiation intensities and/or frequencies, and/or the like may also be measured with sensor devices in accordance with embodiments disclosed herein.

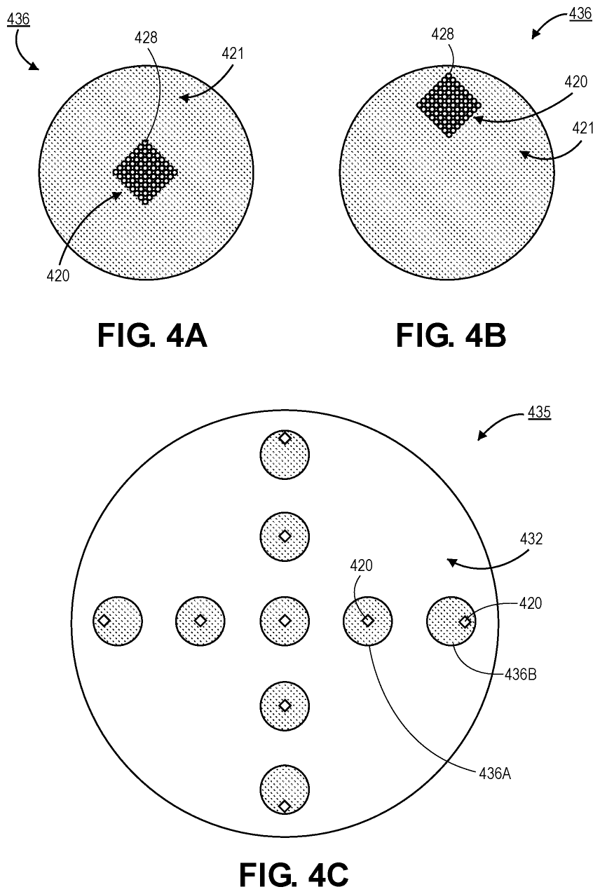

Referring now to FIGS. 4A-4C, a series of plan view illustrations that show sensors 436 (FIGS. 4A and 4B) and a sensor device 435 (FIG. 4C) is shown, in accordance with an embodiment. The differences in the sensors 436 is the location of the group 420 of holes 428. FIG. 4C illustrates an example of how different sensor 436 layouts can be leveraged within a single senor device 435 for improved sensing coverage.

Referring now to FIG. 4A, a plan view illustration of an RFEA sensor 436 is shown, in accordance with an embodiment. In an embodiment, the RFEA sensor 436 may comprise a top housing 421. In an embodiment, a group 420 of holes 428 may be provided on the housing 421 (e.g., the top surface of the housing 421). In the illustrated embodiment, the group 420 is substantially centered at a center point of the top surface of the housing 421. Such a sensor 436 may be referred to as a symmetric sensor 436.

Referring now to FIG. 4B, a plan view illustration of an RFEA sensor 436 is shown, in accordance with an embodiment. In an embodiment, the RFEA sensor 436 may comprise a top housing 421. In an embodiment, a group 420 of holes 428 may be provided on the housing 421 (e.g., the top surface of the housing 421). In the illustrated embodiment, the group 420 is substantially off-center from a center point of the top surface of the housing 421. Such a sensor 436 may be referred to as an asymmetric sensor 436. As shown, the group 420 includes holes 428 that are proximate to an outer edge of the sensor 436. This can allow for improved edge detection, as will be described in greater detail below.

Referring now to FIG. 4C, a plan view illustration of a sensor device 435 is shown, in accordance with an embodiment. In an embodiment, the sensor device 435 is similar to any of the sensor devices described in greater detail herein. In an embodiment, the sensor device 435 may comprise a plurality of RFEA sensors 436 distributed across a lid 432 of the sensor device 435. The sensors 436 may include symmetric sensors 436A and asymmetric sensors 436B. The symmetric sensors 436A may have groups 420 of holes (not individually shown) that are at a center of the symmetric sensors 436A. The asymmetric sensors 436B may have groups 420 of holes that are at the outer edge of the asymmetric sensors 436B. Further, the asymmetric sensors 436B are oriented so that the groups 420 are proximate to the outer edge of the lid 432. This allows for plasma properties to be sensed even closer to the edge of the sensor device 435. This is useful since edge effects are often difficult to control and predict, and having information about the plasma process proximate to the edge of a wafer can be particularly beneficial.

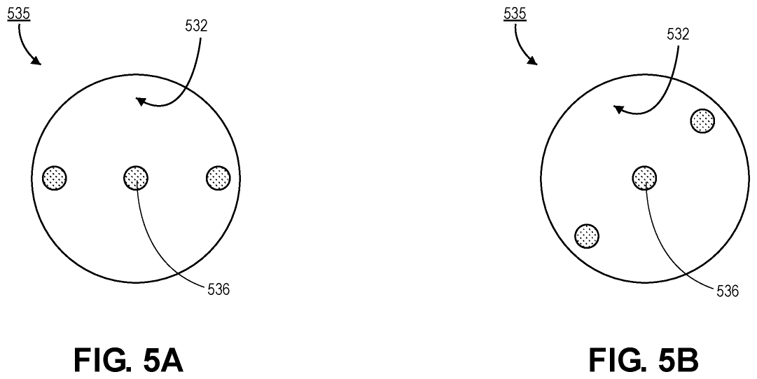

In the embodiment shown in FIG. 4C, the sensors 436 are distributed in a cross pattern to provide edge-to-edge information in at least two directions. However, such sensor coverage may also be obtained using a smaller number of sensors. An example of such a process is shown in FIGS. 5A-5C.

Referring now to FIG. 5A, a plan view illustration of a sensor device 535 is shown, in accordance with an embodiment. In an embodiment, the sensor device 535 may be similar to any sensor device described in greater detail herein. In an embodiment, the sensor device 535 may comprise a lid 532 with sensors 536 embedded and/or placed on the lid 532. In the illustrated embodiment, the sensors 536 are aligned in a line across a width of the sensor device 535. In an embodiment, the sensors 536 may be RFEA sensors 536 and/or similar to any of the sensors described in greater detail herein. While three sensors 536 in a line across a diameter of the lid 532 are shown in FIGS. 5A-5C, it is to be appreciated that any arrangement of sensors 536 distributed across the surface of the lid 532 may be used (with suitable rotation) in accordance with various embodiments. For example, FIG. 5D provides an illustration of three sensors 536 between a center of the sensor device 535 and an edge of the sensor device 535. Such a sensor device 535 can be rotated to provide full surface measurements as well.

In such an embodiment, the sensor device 535 will provide edge-to-edge plasma diagnostics in one direction. However, if the sensor device 535 is rotated, additional information may be provided. For example, FIG. 5B shows the sensor device 535 rotated by approximately 45°, and FIG. 5C shows the sensor device 535 rotated by approximately 90°. These rotations can be provided by an aligner that is coupled to the plasma chamber (not shown). Since the sensor device 535 can pass into and out of the chamber without venting the chamber, making such rotations is simple and does not require sufficient down time compared to existing solutions.

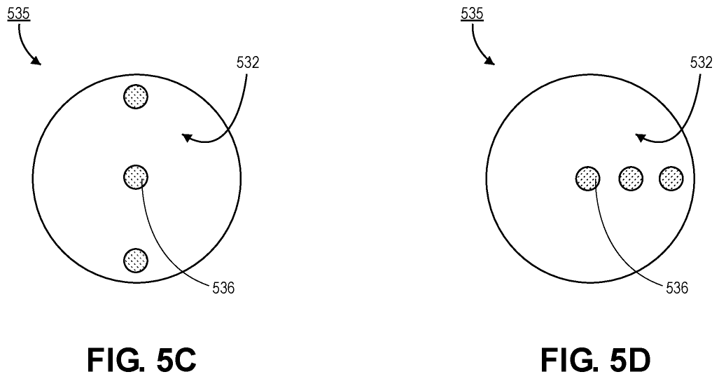

Embodiments disclosed herein may include sensor devices that are compatible with many different types of chambers, tools, systems, and/or the like. In some embodiments, the chambers may be augmented to include intermediate antennas that can be used to improve wireless communications between the sensor device and an external component (e.g., a server, controller, and/or the like). An example of such a chamber is shown in FIG. 6.

Referring now to FIG. 6, a cross-sectional illustration of a tool chamber 650 is shown, in accordance with an embodiment. In an embodiment, the chamber 650 may be a tool compatible with sensor devices 635, such as those described in greater detail herein. For example, the chamber 650 may comprise a chamber body 651 capable of supporting a vacuum environment. A spacer 653 may support a showerhead 654, and an enclosure 655 or lid may cover the showerhead 654. A plasma source 656 may be coupled to the enclosure 655. The plasma source 656 may be a remote plasma source (RPS), an inductively coupled plasma (ICP) source, a capacitively coupled plasma (CCP) source, a microwave plasma source, or any other suitable plasma source. The plasma may operate at any suitable frequency. For example, plasma frequencies of approximately 2 MHz, approximately 13 MHz, approximately 27 MHz, approximately 40 MHz, or the like may be used. Power values between approximately 100 W and 10 kW may be suitable for RF applications, and power values between approximately 100 W and 50 kW or more may be suitable for DC applications in some embodiments. Though, any frequency or power may be used in other embodiments. In an embodiment, a bias 657 may be coupled between the pedestal 652 and a ground 658. In an embodiment, the chamber 650 may be suitable for sputtering, deposition (e.g., plasma enhanced chemical vapor deposition, plasma enhanced atomic layer deposition, etc.), etching processes (e.g., conductor etch, dielectric etch, etc.), plasma implantation processes, plasma treatment processes, or any other plasma process.

In an embodiment, the sensor device 635 may comprise a wireless communications module 644. The wireless communications module 644 may be similar to any of those described in greater detail herein. For example, the wireless communications module 644 may comprise a Bluetooth compatible wireless system. In an embodiment, the wireless communications module 644 may be communicatively coupled (over a wireless connection) to an intermediate antenna within the chamber 650. For example, intermediate antenna 661 may be provided within an exhaust line 659, and intermediate antenna 661 may be provided on (or in) the pedestal 652.

It is to be appreciated that the intermediate antennas may be provided at any location within the chamber body 651 where they will not be significantly impacted by the plasma environment (e.g., due to excessive interference, harsh environmental conditions or chemistries, and/or the like). For example, the pedestal 652 is a good location because the intermediate antenna 662 can be shielded from the plasma by hiding the intermediate antenna 662 below the pedestal 652, providing the intermediate antenna 662 along a sidewall of the pedestal 652, or embedding the intermediate antenna 662 in the pedestal 652. Similarly, placing an intermediate antenna 661 in the exhaust line 659 shields the intermediate antenna 661 from the plasma.

A wireless link 665 is provided between the communications module 644 and the intermediate antenna 661, and a wireless link 663 is provided between the communications module 644 and the intermediate antenna 662. While two intermediate antennas 661 and 662 are shown, it is to be appreciated that embodiments may include a single intermediate antenna. As shown, the wireless links 663 and 665 do not pass through the chamber body 651 of the chamber 650. As such, there is no concern about the generation of a Faraday cage around the sensor device 635.

In order to deliver signals out of the chamber 650, the intermediate antennas 661 and/or 662 may be physically connected to an external component 660 by wires 666 and/or 667. Since the intermediate antennas 661 and 662 do not move between chambers (like the sensor device 635 does), the hard-wired configuration does not generate significant issues for the chamber 650. The external component 660 may be a server, computing system, and/or the like. The external component 660 may control operation of one or more of the chamber 650, a larger tool that includes the chamber 650, an entire fabrication facility, the sensor device 635, or the like.

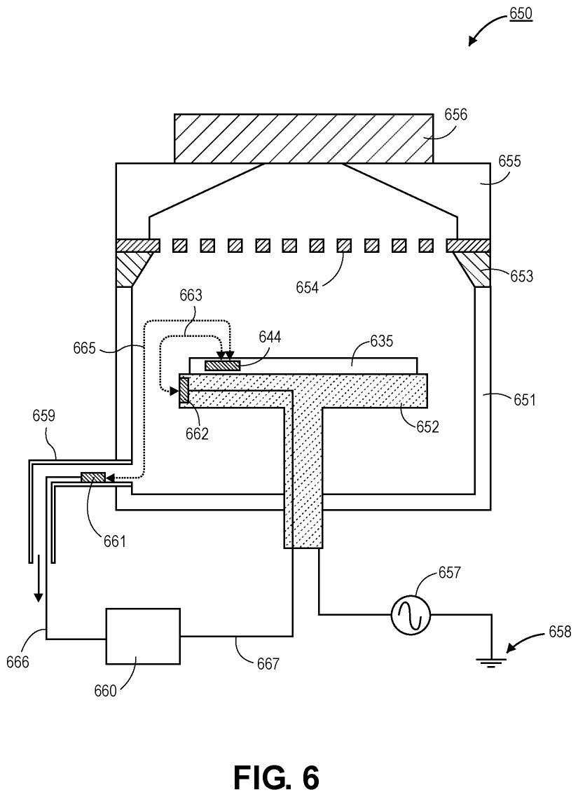

Referring now to FIG. 7, a process flow diagram of a process 770 for measuring a plasma property in a chamber is shown, in accordance with an embodiment. In an embodiment, the process 770 may begin with operation 771, which comprises delivering a sensor device to a chamber without the chamber being vented. In an embodiment, the sensor device may be similar to any of the sensor devices described in greater detail herein. For example, the sensor device may comprise one or more RFEA sensors with a wafer-like form factor. The sensor device may comprise a wireless communications module, such as those described in greater detail herein. In an embodiment, the sensor device may be delivered to the chamber through the use of wafer handling robots that pass the sensor device through a larger tool, such as a cluster tool.

In an embodiment, the process 770 may continue with operation 772, which comprises measuring a plasma property within the chamber with the sensor device. In an embodiment, RFEA sensors may record an electrical current that is related to a particular plasma property. A digitized record of the current may be processed and/or stored by the sensor device. In some embodiments, the plasma property data may be wirelessly transmitted outside of the chamber using the wireless communications module (e.g., through Bluetooth protocols, frequency modulation, etc.). In some instances, an intermediate antenna, similar to those described in greater detail herein, may be used to complete the transfer of data from the sensor device out of the chamber.

In an embodiment, the process 770 may continue with operation 773, which comprises removing the sensor device from the chamber without the chamber being vented. In an embodiment, the sensor device may be removed with wafer robot handling equipment or the like. After removal from the chamber, the sensor device may be sent to a docking station for charging, data downloading/uploading, storage, cooling, or any other suitable purpose.

The process 770 and associated sensor device overcomes several of the existing issues with RFEA solutions that are bulky and do not lend themselves to seamless data collection. Particularly, when a measurement is desired, existing RFEA solutions require that the plasma chamber be taken offline. This includes venting the chamber (i.e., releasing the vacuum within the chamber), and opening the chamber lid. The RFEA device is then inserted into the chamber, and the lid is closed. The chamber is pumped back down and re-seasoned. Measurements can then be made. The venting process is repeated in order to remove the RFEA device, and the chamber needs to be seasoned in order to return to production. This process can take up to a day, or longer. Accordingly, measurements can only be made infrequently, and flexibility to make adjustments to a given plasma process is limited. In contrast, process 770 allows for inserting and removing the sensor device into/from the chamber with existing wafer handling robots. This allows for the elimination of venting the chamber. Further, the wireless communication included in some embodiments of process 770 allows for wired connections to the sensor device to be omitted. This further enhances portability of the sensor device and lowers the burden of taking measurements.

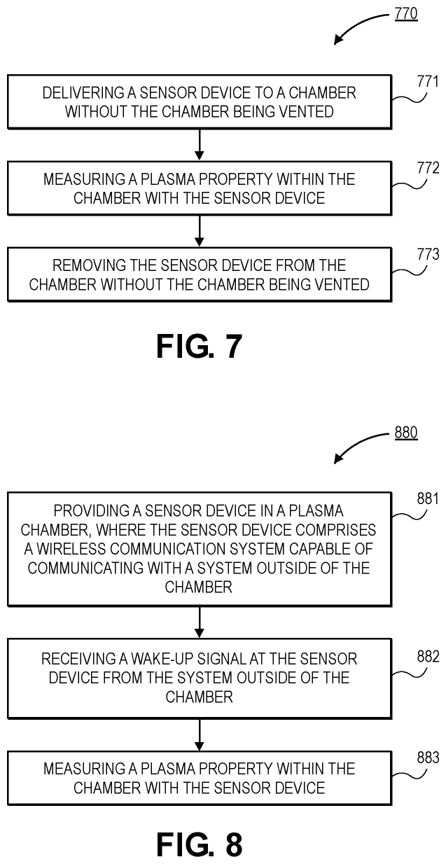

Referring now to FIG. 8, a process flow diagram of a process 880 is shown, in accordance with an additional embodiment. The process 880 is used in order to improve battery utilization of the sensor device. Particularly, since the sensor device is battery operated, embodiments of process 880 may include a series of operations for activating the sensor device and putting the sensor device to sleep.

In an embodiment, the process 880 may begin with operation 881, which comprises providing a sensor device in a plasma chamber. In an embodiment, the sensor device may comprise a wireless communication system capable of communicating with a system outside of the chamber. In an embodiment, the sensor device may be similar to any of the sensor devices described in greater detail herein.

In an embodiment, the process 880 may continue with operation 882, which comprises receiving a wake-up signal at the sensor device from the system outside of the chamber. Prior to receiving the wake-up signal, the sensor device may be in a “sleep” state. That is, the sensor device may not be fully operational, and one or more systems may be temporarily disabled or otherwise not drawing significant power. While “asleep” the sensor device may have power running in order to detect and/or receive the wake-up signal. The wake-up signal may be a command that initiates one or more processes on the sensor device. For example, the wake-up signal may initiate a data recording session on the sensor device so that the sensors begin to scan and record data relating to a plasma property in the chamber, as indicated in operation 883. For example, operation 883 may comprise measuring a plasma property within the chamber with the sensor device. After measuring the plasma property for any suitable duration of time, the sensor device may return back to a sleep mode. Returning to sleep mode may be initiated by either the passage of a period of time or the receipt of another signal that directs the sensor device to go back to sleep mode.

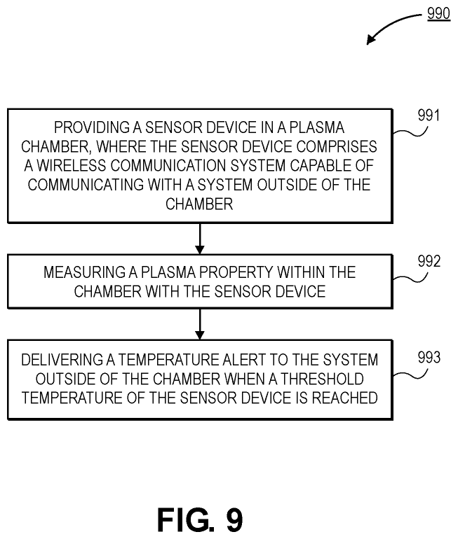

Referring now to FIG. 9, a process flow diagram of a process 990 for protecting a sensor device from overheating is shown, in accordance with an embodiment. In an embodiment, the process 990 may begin with operation 991, which comprises providing a sensor device in a plasma chamber. In an embodiment, the sensor device may be similar to any of the sensor devices described in greater detail herein. For example, the sensor device may comprise a wireless communication system capable of communicating with a system outside of the chamber.

In an embodiment, the process 990 may continue with operation 992, which comprises measuring a plasma property within the chamber with the sensor device. For example, an RFEA sensor may measure one or more of ion density, ion flux, and/or ion energy distribution of a plasma.

In an embodiment, the process 990 may continue with operation 993, which comprises delivering a temperature alert to the system outside of the chamber when a threshold temperature of the sensor device is reached. In an embodiment, the sensor device may comprise a temperature sensor that is able to monitor the temperature of the sensor device. When the temperature sensor measures a temperature at or over the threshold temperature (e.g., 100° C. or greater, 120° C. or greater, 150° C. or greater, or 200° C. or greater), the sensor device may send out the alert.

In some embodiments, the system outside of the chamber may be equipped with an interlock device that shuts down the plasma process of the chamber in response to the temperature alert. In this way, the temperature of the sensor device may be prevented from being raised significantly above the threshold temperature. In some instances, the system outside of the chamber may also direct wafer handling equipment coupled to the chamber to extract the sensor device from the chamber. The wafer handling equipment may also deliver the sensor device to a cooling chamber in order to more quickly reduce a temperature of the sensor device.

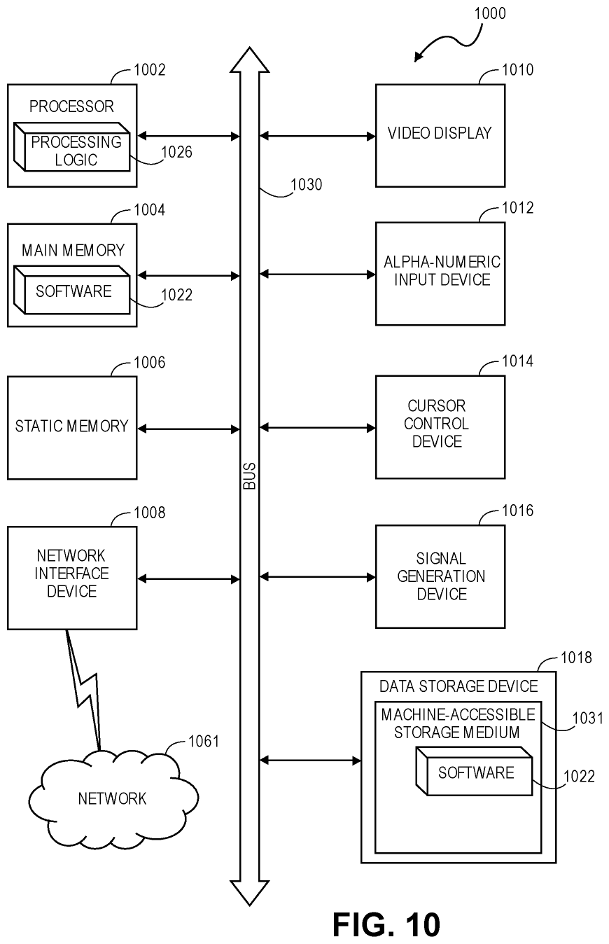

Referring now to FIG. 10, a block diagram of an exemplary computer system 1000 of a processing tool is illustrated in accordance with an embodiment. In an embodiment, computer system 1000 is coupled to and controls processing in the processing tool. Computer system 1000 may be connected (e.g., networked) to other machines in a Local Area Network (LAN), an intranet, an extranet, or the Internet. Computer system 1000 may operate in the capacity of a server or a client machine in a client-server network environment, or as a peer machine in a peer-to-peer (or distributed) network environment. Computer system 1000 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 1000, the term “machine” shall also be taken to include any collection of machines (e.g., computers) that individually or jointly execute a set (or multiple sets) of instructions to perform any one or more of the methodologies described herein.

Computer system 1000 may include a computer program product, or software 1022, having a non-transitory machine-readable medium having stored thereon instructions, which may be used to program computer system 1000 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 1000 includes a system processor 1002, a main memory 1004 (e.g., read-only memory (ROM), flash memory, dynamic random access memory (DRAM) such as synchronous DRAM (SDRAM) or Rambus DRAM (RDRAM), etc.), a static memory 1006 (e.g., flash memory, static random access memory (SRAM), etc.), and a secondary memory 1018 (e.g., a data storage device), which communicate with each other via a bus 1030.

System processor 1002 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 1002 may also be one or more special-purpose processing devices such as an application specific integrated circuit (ASIC), a field programmable gate array (FPGA), a digital signal system processor (DSP), network system processor, or the like. System processor 1002 is configured to execute the processing logic 1026 for performing the operations described herein.

The computer system 1000 may further include a system network interface device 1008 for communicating with other devices or machines. The computer system 1000 may also include a video display unit 1010 (e.g., a liquid crystal display (LCD), a light emitting diode display (LED), or a cathode ray tube (CRT)), an alphanumeric input device 1012 (e.g., a keyboard), a cursor control device 1014 (e.g., a mouse), and a signal generation device 1016 (e.g., a speaker).

The secondary memory 1018 may include a machine-accessible storage medium 1031 (or more specifically a computer-readable storage medium) on which is stored one or more sets of instructions (e.g., software 1022) embodying any one or more of the methodologies or functions described herein. The software 1022 may also reside, completely or at least partially, within the main memory 1004 and/or within the system processor 1002 during execution thereof by the computer system 1000, the main memory 1004 and the system processor 1002 also constituting machine-readable storage media. The software 1022 may further be transmitted or received over a network 1061 via the system network interface device 1008. In an embodiment, the network interface device 1008 may operate using RF coupling, optical coupling, acoustic coupling, or inductive coupling.

While the machine-accessible storage medium 1031 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. An apparatus, comprising:
a housing;
a plasma sensor on a surface of the housing; and
a computing system within the housing and electrically coupled to the plasma sensor, wherein the computing system comprises:
a battery;
a board;
a processing unit on the board;
a memory coupled to the processing unit; and
a wireless communication module coupled to the processing unit.

2. The apparatus of claim 1, wherein the wireless communication module comprises an RF antenna.

3. The apparatus of claim 2, wherein the housing comprises a ceramic inlay over the RF antenna.

4. The apparatus of claim 1, wherein the wireless communication module is electrically coupled to the board, and wherein the wireless communication module operates in accordance with a Bluetooth protocol with one or more antennas.

5. The apparatus of claim 1, wherein the computing system further comprises a temperature sensor.

6. The apparatus of claim 1, wherein a thickness of the housing is less than 10 mm.

7. The apparatus of claim 1, wherein a weight of the apparatus is less than 1,000 grams.

8. The apparatus of claim 1, wherein the plasma sensor comprises one or more of a retarding field energy analyzer (RFEA), a Faraday cup, an ion angle measurement sensor, or a radical sensor.

9. The apparatus of claim 8, wherein the RFEA comprises a group of holes through an outer surface of the RFEA, and wherein the group of holes is off-center from a center point of the RFEA.

10. The apparatus of claim 1, wherein the housing comprises aluminum, aluminum nitride, a sintered aluminum nitride powder, a ceramic, a light metal alloy, or a machinable glass.

11. A method of characterizing a plasma in a chamber, comprising:
delivering a sensor device to the chamber without the chamber being vented, wherein the sensor device comprises:
a housing;
a plasma sensor on the housing; and
a computing system within the housing, wherein the computing system comprises a battery, a processor, and a wireless communications system;
measuring a plasma property within the chamber with the sensor device; and
removing the sensor device from the chamber without the chamber being vented.

12. The method of claim 11, further comprising:
transmitting data related to the plasma property to a device external to the chamber with the wireless communications system.

13. The method of claim 11, further comprising:
activating the sensor device in response to a wake-up signal from an external device and/or transferring data between the sensor device and the external device.

14. The method of claim 11, further comprising:
delivering a temperature alert to an external device from the sensor device when the sensor device determines that a temperature is above a threshold temperature; and
stopping a plasma process within the chamber in response to the temperature alert.

15. The method of claim 14, wherein the threshold temperature is 80° C. or higher.

16. The method of claim 14, wherein the sensor device is delivered to a cooling chamber after the plasma process is stopped.

17. A semiconductor processing tool, comprising:
a factory interface;
a transfer chamber;
a load lock coupled between the factory interface and the transfer chamber; and
a processing chamber coupled to the transfer chamber, wherein the processing chamber comprises:
a pedestal for supporting a substrate;
an exhaust line for removing gasses from the processing chamber;
a plasma source opposite from the pedestal; and
an antenna within the processing chamber, wherein the antenna has a wired connection to outside of the processing chamber.

18. The semiconductor processing tool of claim 17, wherein the antenna is within the exhaust line.

19. The semiconductor processing tool of claim 17, wherein the antenna is on or inside the pedestal and/or wherein the antenna faces away from the plasma source.

20. The semiconductor tool of claim 17, wherein the pedestal comprises an electrostatic chuck with thermal control configured to limit a temperature of the sensor device.
